(19) United States
(12) Patent Application Publication
(10) Pub. No.: US 2008/0084662 A1
(43) Pub. Date: Apr. 10, 2008

(54) Heat-dissipating device

(75) Inventors: Yi-Nien Hsin, Taipei Hsien (TW); Man-Kim Kwan, Taipei Hsien (TW)

Correspondence Address: BIRCH STEWART KOLASCH & BIRCH, PO BOX 747, FALLS CHURCH, VA, 22040-0747, US

(73) Assignee: GIGA-BYTE TECHNOLOGY CO., LTD.

(21) Appl. No.: 11/543,137

(22) Filed: Oct. 5, 2006

(51) Int. Cl. H05K 7/20

(52) U.S. Cl. 361/695

(57) ABSTRACT

A heat-dissipating device includes a heat sink and a fastening mechanism. The heat sink comprises a body and a plurality of fins perpendicular to the body. The fastening mechanism connects to the heat sink and has a sidewall perpendicular to the fins. The sidewall is flush with or lower than the body.

### FIELD OF THE INVENTION

The invention relates to heat-dissipation, and particularly to an electronic device utilizing an improved fastening mechanism to raise efficiency of heat-dissipation.

### DESCRIPTION OF THE RELATED ART

Current electronic device trends toward compact size and portability that has made heat-dissipation an important consideration. Referring to FIG. 1A, a conventional heat-dissipating device 1 for cooling a central processing unit (CPU) comprises a fan 2, a heat sink 3 and a fastening mechanism 4. The fan 2 connects to the heat sink 3. The fastening mechanism 4 fixes the heat sink 3 on the CPU. When the electronic device 1 is in operation, heat produced by the CPU is transmitted to the heat sink 3 quickly. Airflow from fan 2 reaches to the fins 3f of the heat sink 3, exhausting heat accumulated thereon through gaps therebetween.

Referring to FIG. 1B, when the fastening mechanism 4 and the heat sink 3 of the conventional heat-dissipating device 1 are connected, a sidewall of the fastening mechanism 4 partially blocks the gaps between the fins 3f, reducing airflow from the fan 2. Furthermore, the airflow must curve (as shown by arrows in FIG. 1B) before being exhausted, increasing energy consumption.

### SUMMARY OF THE INVENTION

The invention provides a heat-dissipating device, comprising a heat sink and a fastening mechanism. The heat sink comprises a body and a plurality of fins perpendicular to the body. The fastening mechanism connects to the heat sink and has a sidewall perpendicular to the fins. The sidewall is flush with or lower than the body.

The heat-dissipating device further comprises a fan connecting to the fins.

The fastening mechanism comprises a base and a fastening element fixing the heat sink on the base.

The invention further provides an electronic device comprising a heat sink and a fastening mechanism. The heat sink comprises a body and a plurality of fins perpendicular to the body. The fastening mechanism connects to the heat sink and has a sidewall perpendicular to the fins. The sidewall is flush with or lower than the body.

The electronic device further comprises a printed circuit board and a central processing unit disposed on the printed circuit board, wherein the fastening mechanism fixes the heat sink on the central processing unit. The body abuts against the central processing unit.

The electronic device further comprises a fan connecting to the fins.

The fastening mechanism comprises a base and a fastening element fixing heat sink thereon.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1A is a schematic view of a conventional heat-dissipating device;

FIG. 1B is a sectional view along line A-A in FIG. 1A;

FIG. 2A is a schematic view of the invention;

FIG. 2B is a sectional view along line A-A in FIG. 1A

FIG. 2C is a sectional view of a variant embodiment of the invention.

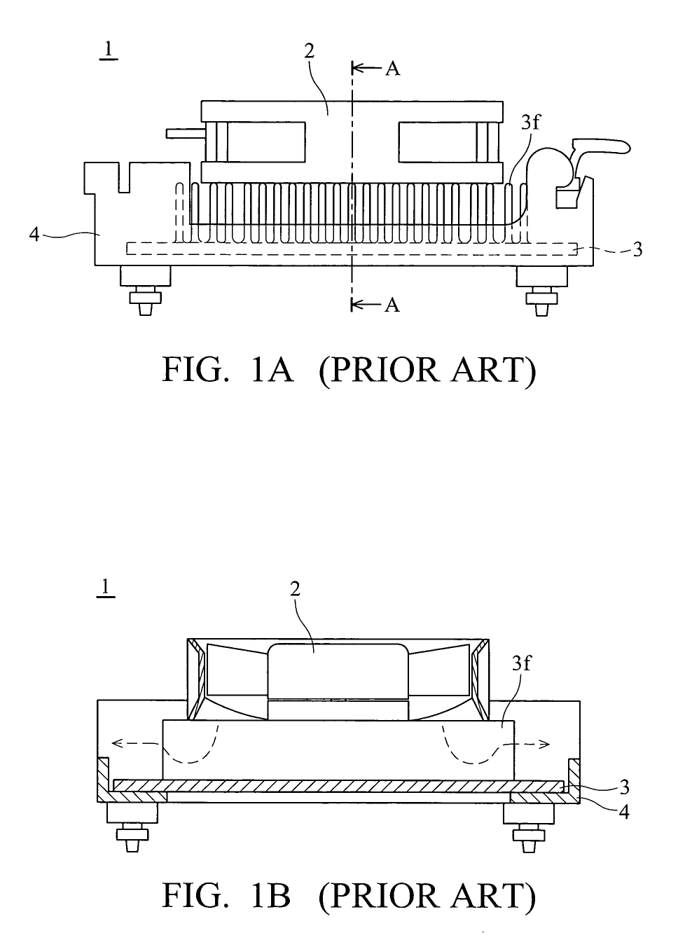

### DETAILED DESCRIPTION OF THE INVENTION

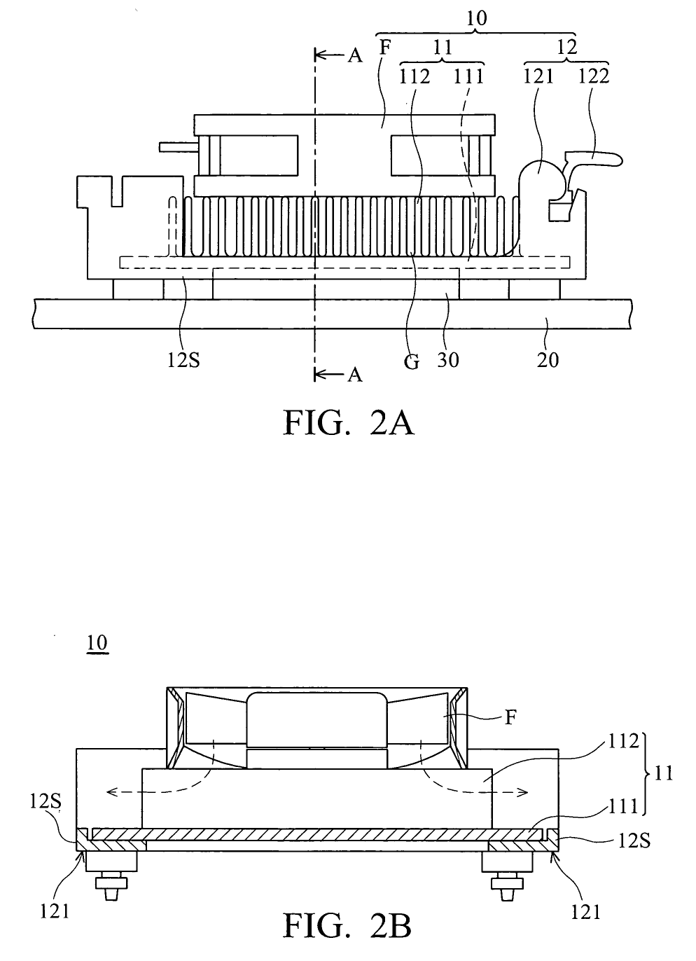

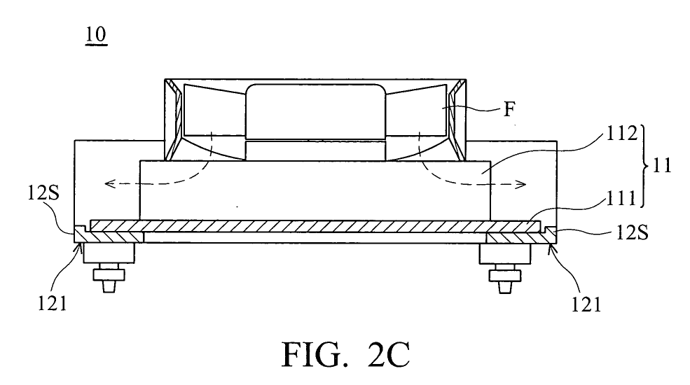

Referring to FIG. 2A, in the embodiment, the electronic device comprises a heat-dissipating device 10, a printed circuit board 20 and a central processing unit (CPU) 30. The heat-dissipating device 10 dissipates heat produced by the CPU 30 and further comprises a fan F, a heat sink 11 and a fastening mechanism 12.

It should be noted that the CPU 30 of the embodiment is the main heat source, so the heat-dissipating device 10 cools the CPU 30, but it is not limited thereto. The heat-dissipating device 10 can be utilized for any other heat source.

The heat sink 11 comprises a body 111 and a plurality of fins 112. The fins 112 are disposed on the body 111 perpendicularly. The fastening mechanism 12 comprises a base 121 and a fastening element 122.

The fan F is disposed on a side of the heat sink 11 and connected with the fins 112. The body 111 is disposed on the base 121. By engaging the fastening element 122 and the base 121, the body 111 is fixed therebetween, fastening the heat sink 11 on the fastening mechanism 12. It should be noted that a sidewall 12S of the fastening mechanism 12 is flush with the body 111 (as shown in FIG. 2B), or lower than the body 111 (as shown in FIG. 2C).

The CPU 30 is disposed on the printed circuit board 20, and the fastening mechanism 12 is disposed on the printed circuit board 20, such that the body 111 of the heat sink 11 can be attached to the CPU 30. Heat produced by the CPU 30 is then quickly transmitted to the heat sink 11 by abutting the heat sink 12 against the CPU 30.

In the embodiment, the sidewall 12S is flush with the body 111, or lower than the body 111, allowing the fins 112 to be completely exposed. While gaps G between the fins 112 are not blocked by the sidewall 12S. Consequently, the airflow provided by the fan F, moving toward the fins, is smoothly exhausted from the gaps G between the fins 112.

The fastening mechanism 12 is meliorated within the limited space of the electronic device. Not only is the original structure of the electronic device maintained, but intensity of the airflow is improved. In addition, energy is conserved, raising heat-dissipating efficiency.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A heat-dissipating device, comprising:
a heat sink comprising a body and a plurality of fins perpendicular to said body; and
a fastening mechanism connecting to said heat sink and having a sidewall perpendicular to said fins;
wherein said sidewall is flush with said body or lower than said body.

2. The heat-dissipating device as claimed in claim 1, further comprising a fan connecting to said fins.

3. The heat-dissipating device as claimed in claim 1, wherein said fastening mechanism comprises a base and a fastening element, with said heat sink disposed on said base and said body of said heat sink is fixed thereon by said fastening element.

4. An electronic device, comprising:
a heat sink comprising a body and a plurality of fins perpendicular to said body; and
a fastening mechanism connecting to said heat sink and having a sidewall perpendicular to said fins;
wherein said sidewall is flush with said body or lower than said body.

5. The electronic device as claimed in claim 4, further comprising a printed circuit board and a central processing unit disposed on said printed circuit board, wherein said fastening mechanism fixes said heat sink on said central processing unit.

6. The electronic device as claimed in claim 5, wherein said body abuts against said central processing unit.

7. The electronic device as claimed in claim 4, further comprising a fan connecting to said fins.

8. The electronic device as claimed in claim 4, wherein said fastening mechanism comprises a base and a fastening element, with said heat sink disposed on said base and said body of said heat sink is fixed thereon by said fastening element.
